(19) United States
(12) Patent Application Publication
(10) Pub. No.: US 2016/0365387 A1
(43) Pub. Date: Dec. 15, 2016

(54) IN-CELL TOUCH OLED DISPLAY AND METHOD FOR PRODUCING SAME

(71) Applicant: EverDisplay Optronics (Shanghai) Limited, Shanghai (CN)

(72) Inventor: Xinyuan Wei, Shanghai (CN)

(73) Assignee: EverDisplay Optronics (Shanghai) Limited

(21) Appl. No.: 15/096,845

(22) Filed: Apr. 12, 2016

(30) Foreign Application Priority Data
Jun. 15, 2015 (CN) 201510330944.X

(51) Int. Cl. H01L 27/32; H01L 51/52; H01L 51/56; G06F 3/041

(52) U.S. Cl. CPC H01L 27/323; G06F 3/0412; H01L 51/5246; H01L 51/56; H01L 51/5281; G06F 2203/04103

(57) ABSTRACT

An in-cell touch OLED display and its production method are provided. A low temperature poly-silicon (LTPS) glass and a cover glass are provided. An organic electroluminescent device is disposed on an upper face of the LTPS glass. A touch sensing layer is disposed on a lower face of the cover glass. The lower face of the cover glass is bonded to the upper face of the LTPS glass. A first connection area is on at least one side of the LTPS glass. A second connection area is defined on at least one side of the cover glass. A portion of the cover glass is cut to expose the first connection area. A portion of the LTPS glass is cut to expose the second connection area. The first connection area is connected to a chip film. The second connection area is connected to a flexible printing circuit.

### CROSS REFERENCE TO RELATED APPLICATIONS

This application is based upon and claims priority to Chinese Patent Application No. 201510330944X, filed on Jun. 15, 2015, the entire contents of which are incorporated herein by reference.

### BACKGROUND

The present disclosure relates to an organic light-emitting diode (OLED) display and, more particularly, to an in-cell touch OLED display and a method for producing the in-cell touch OLED display.

Good quality in the display effect, an exquisite appearance, a thin, light structure, and a narrow frame have always been the market demands for middle-size and small-size products, particularly smart phones. An organic light-emitting diode (OLED) uses an organic material that emits light through injection and recombination of carrier under the effect of an electric field. OLED has replaced the conventional combination of a liquid crystal display (LCD) and a backlight module and is lighter and thinner. However, although the OLED without the backlight module is lighter and thinner than the conventional liquid crystal display, OLED uses a non-conductive frit in sealing, such that the electricity cannot be conducted from the cover glass to the substrate glass. In this way, AMOLED cannot include an in-cell touch display structure. Namely, the touch transduction functions are integrated inside the display. In this way, how to change the structural design of the OLED display to permit an in-cell touch structure in the OLED display is a meaningful research subject.

### SUMMARY

An objective of the present disclosure is to provide an in-cell touch OLED display and a method for producing the in-cell touch OLED display, providing a thin, light structure for reducing the reflective index and improving the display effect.

The objective is fulfilled by an in-cell touch OLED display and a method for producing the in-cell touch OLED display.

A further objective of the present disclosure is accomplished by a method for producing an in-cell touch OLED display, the method comprising the steps of:

providing a low temperature poly-silicon (LTPS) glass, with an organic electroluminescent device disposed on an upper face of the LTPS glass;

providing a cover glass securely located on top of the LTPS glass and having a touch sensing layer disposed on a lower face of the cover glass;

defining a first connection area on at least one side of the LTPS glass;

defining a second connection area on at least one side of the cover glass;

removing partially the cover glass to leave the first connection area for connection to a chip film; and

removing partially the LTPS glass to leave the second connection area for connection to a flexible printed circuit.

A further objective of the present disclosure is that an in-cell touch OLED display has a low temperature poly-silicon (LTPS) glass, with an organic electroluminescent device disposed on an upper face of the LTPS glass; a cover glass, with a touch sensing layer disposed on a lower face of the cover glass, with the lower face of the cover glass bonded to the upper face of the LTPS glass; at least one side of the LTPS glass comprising a first connection area on, with the first connection area adapted to be connected to a chip film; at least one side of the cover glass comprising a second connection area on, with the second connection area adapted to be connected to a flexible printed circuit; a first opening in the cover glass and the first connection area of the LTPS glass exposed via the first opening; and a second opening in the LTPS glass and the second connection area of the cover glass exposed via the second opening.

The advantageous effects of the present disclosure are as follows:

1. The organic electroluminescent device according to an embodiment of the disclosure is disposed on the upper face of the LTPS glass, and the touch sensing layer is disposed on the lower face of the cover glass. The first connection area is defined on at least one side of the LTPS glass. The second connection area is defined on at least one side of the cover glass. By such an arrangement, after the lower face of the cover glass has been glued to the upper face of the LTPS glass, a portion of the cover glass can be cut away to expose the first connection area of the LTPS glass, and a portion of the LTPS glass can be cut away to expose the second connection area of the cover glass. In this way, the exposed first connection area can be used to connect with the chip film, and the exposed second connection area can be used to connect with the flexible printed circuit, both of which does not require a change in the outline of the OLED display. By accomplishing the connection of the in-cell touch sensing layer and the flexible printed circuit between the LTPS glass and the cover glass after packaging, the OLED display includes an in-cell touch control structure. Furthermore, the electrical connection between the LTPS glass and the cover glass can be achieved by the exposed chip film and the exposed flexible printed circuit. A light, thin in-cell touch control display structure is, in this way, formed to reduce the reflective index of the OLED display, increasing the display effect.

2. The chip film and the flexible printed circuit are respectively connected to positions outside of the active area of the OLED display, and the second opening of the LTPS glass and the first opening of the cover glass are located outside of the active area of the OLED display, avoiding adverse influence on the effective emission of the OLED display.

3. The present disclosure does not change the outline of the OLED display and does not increase the length of the substrate glass or the cover glass, such that the rate of typesetting of the OLED display is not changed. In this way, the frame of the OLED display can be made narrower.

The present disclosure will be further described in connection with the accompanying drawings and specific embodiments.

### DESCRIPTION OF THE DRAWINGS

FIG. 1 is a diagrammatic front view of an in-cell touch OLED display of an embodiment according to the present disclosure.

FIG. 2 is an exploded perspective view illustrating an LTPS glass and a cover glass of the in-cell touch OLED display of FIG. 1.

FIG. 3 is an enlarged view of a portion of the in-cell touch OLED display of FIG. 1.

FIG. 4 is a diagrammatic rear view of the in-cell touch OLED display of an embodiment according to the present disclosure.

FIG. 5 is an exploded, perspective view illustrating the LTPS glass and the cover glass of the in-cell touch OLED display of FIG. 4.

FIG. 6 is an enlarged view of a portion of the in-cell touch OLED display of FIG. 4.

FIG. 7 is a diagrammatic front view of an in-cell touch OLED display of another embodiment according to the present disclosure.

FIG. 8 is a diagrammatic rear view of the in-cell touch OLED display of another embodiment according to the present disclosure.

### DETAILED DESCRIPTION

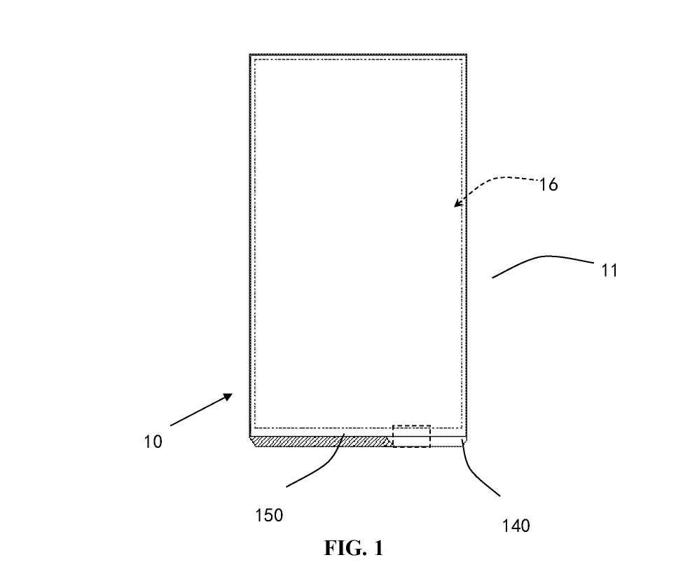

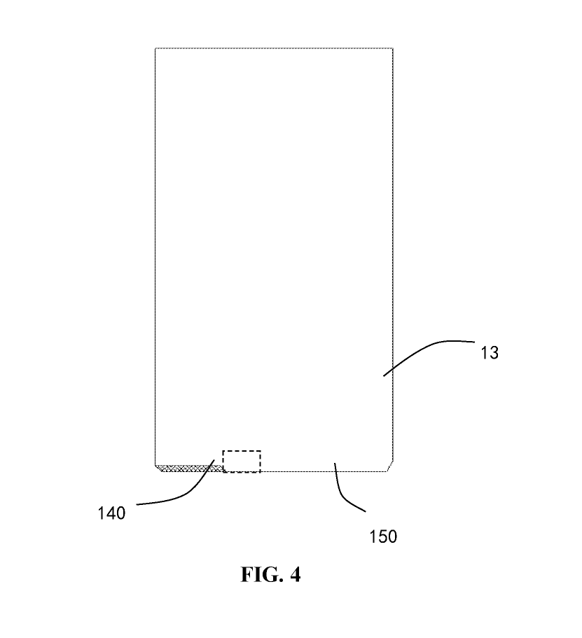

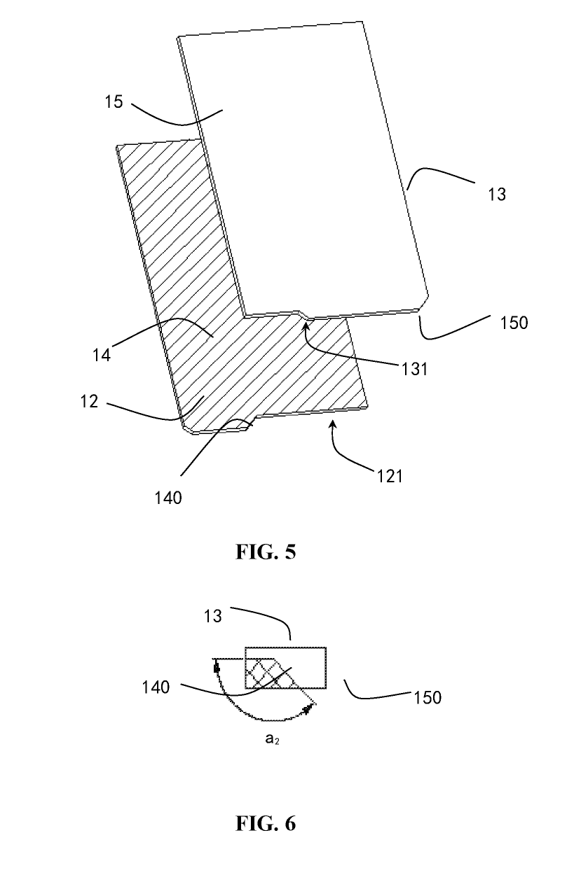

With reference to FIGS. 1-6, an in-cell touch OLED display 10 according to an embodiment of the present embodiment includes, from top to bottom, a polarizer 11, a cover glass 12, and a low temperature poly-silicon (LTPS) glass 13. An organic electroluminescent device 15 is disposed on an upper face of the LTPS glass 13. A touch sensing layer 14 is disposed on a lower face of the cover glass 12. The lower face of the cover glass 12 is bonded to the upper face of the LTPS glass 13 by a frit to seal the cover glass 12 and the LTPS glass 13.

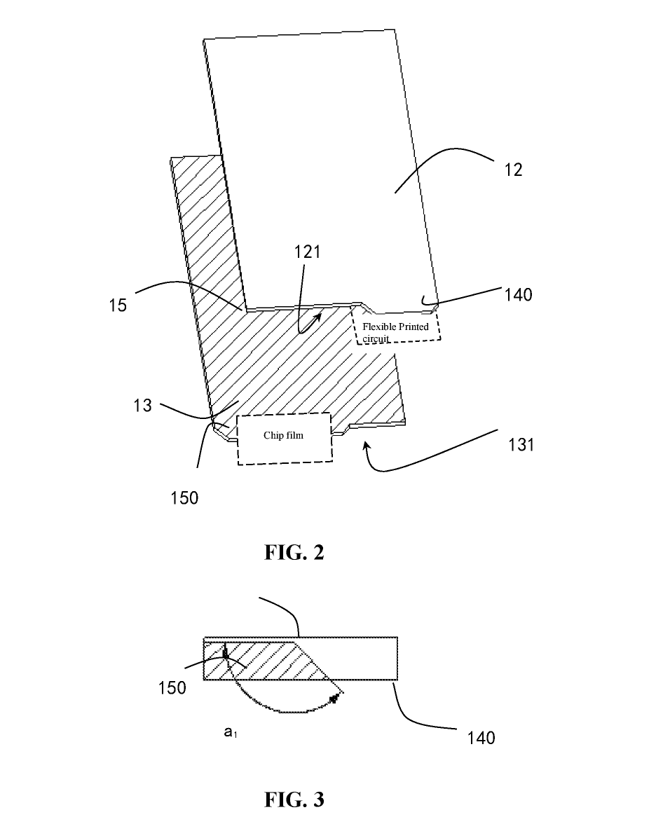

As shown in FIG. 2 the organic electroluminescent device 15 is disposed on the upper face of the LTPS glass 13, and the touch sensing layer 14 is disposed on the lower face of the cover glass 12. Since the cover glass 12 and the LTPS glass 13 are two pieces of glasses of the same size, when the cover glass 12 and the LTPS glass 13 have been sealed to each other by gluing, the organic electroluminescent device 15 and the touch sensing layer 14 are sealed to the gluing face where the cover glass 12 and the LTPS glass 13 are sealed to each other. In this way, it is impossible to directly connect other components (such as a chip film and a flexible printed circuit) to the organic electroluminescent device 15 and the touch sensing layer 14 and is impossible to achieve connection between the organic electroluminescent device 15 and the touch sensing layer 14.

In view of the problem in the connection from the touch sensing layer 14 of the cover glass 12 and the organic electroluminescent device 15 of the LTPS glass 13 to the chip film and the flexible printed circuit after sealing by gluing, the present embodiment provides a novel in-cell touch OLED display 10. Specifically, a first connection area 150 is defined on at least one side of the LTPS glass 13, as shown in FIG. 2. A second connection area 140 is defined on at least one side of the cover glass 12. The first connection area 150 and the second connection area 140 do not overlap with each other. However, since the overall size of the LTPS glass 13 and of the cover glass 12 are identical and coincide perfectly with one another, after the polarizer 11 is affixed in position, the first connection area 150 and the second connection area 140 are revealed as they are mutually complementary to each other.

A first opening 121 is formed in the cover glass 12 with a cutting angle aₗ ranging from 0° to 180°. The cutting length can be of any value, namely, from 0˜∞ mm. In this way, as shown in FIG. 1, the first connection area 150 of the LTPS glass 13 can be exposed from the front side of the OLED display 10 via the first opening 121, such that the first connection area 150 can, later one, be connected to the chip film via the first opening 121. In this way, the first connection area 150 of the LTPS glass 13 after sealing by gluing can be connected to the chip film or can serve as a basis for subsequent electric connection without changing the outline of the OLED display 10.

A second opening 131 is formed in the LTPS glass 13 with a cutting angle a₂ ranging from 0° to 180°, as shown in FIG. 6. The cutting length can be of any value (namely, (0, ∞) mm). In this way, as shown in FIG. 4, the second connection area 140 of the cover glass 12 can be exposed from the back side of the OLED display 10 via the second opening 131. In this way, the second connection area 140 can, later on, be connected to the flexible printed circuit via the second opening 131. In this way, the second connection area 140 of the cover glass 12 after sealing by gluing can be connected to the flexible printed circuit or serves as a basis for subsequent electric connection without altering the outline of the OLED display 10.

In the in-cell touch OLED display 10 according to the present embodiment, the organic electroluminescent device 15 is disposed on the upper face of the LTPS glass 13, and the touch sensing layer 14 is disposed on the lower face of the cover glass 12. The first connection area 150 is defined on at least one side of the LTPS glass 13. The second connection area 140 is defined on at least one side of the cover glass 12. By such an arrangement, after the lower face of the cover glass 12 has been glued to the upper face of the LTPS glass 13, a portion of the cover glass 12 can be cut away to expose the first connection area 150 of the LTPS glass 13, and a portion of the LTPS glass 13 can be cut away to expose the second connection area 140 of the cover glass 12. In this way, the exposed first connection area 150 can, later on, be used to connect with the chip film, and the exposed second connection area 140 can be used to connect with the flexible printed circuit, both of which do not require a change in the outline of the OLED display 10. By accomplishing the connection of the in-cell touch sensing layer 14 and the flexible printed circuit between the LTPS glass 13 and the cover glass 12 after sealing, the OLED display 10 includes an in-cell touch control structure. Furthermore, the electrical connection between the LTPS glass 13 and the cover glass 12 can be achieved by the exposed chip film and the exposed flexible printed circuit. A light, thin in-cell touch control display structure is, in this way, formed to reduce the reflective index of the OLED display 10, increasing the display effect.

With reference to FIG. 1, the first connection area 150 and the second connection area 140 are located outside of an active area 16 of the OLED display 10 without adversely affecting the effective emission of the OLED display 10. The first connection area 150 and the second connection area 140 do not overlap with each other. In a case that the first connection area 150 of the LTPS glass 13 is located on a left side of a bottom of the LTPS glass 13 located outside of the active area 16 of the OLED display 10, a left side of a bottom of the cover glass 12 aligned with the first connection area 150 is cut away to expose the first connection area 150. In this case, as shown in FIG. 4, the second connection area 140 of the cover glass 12 is located on a right side of the bottom of the cover glass 12 located outside of the active area 16 of the OLED display 10. A right side of the bottom of the LTPS glass 13 aligned with the second connection area 140 is cut away to expose the second connection area 140.

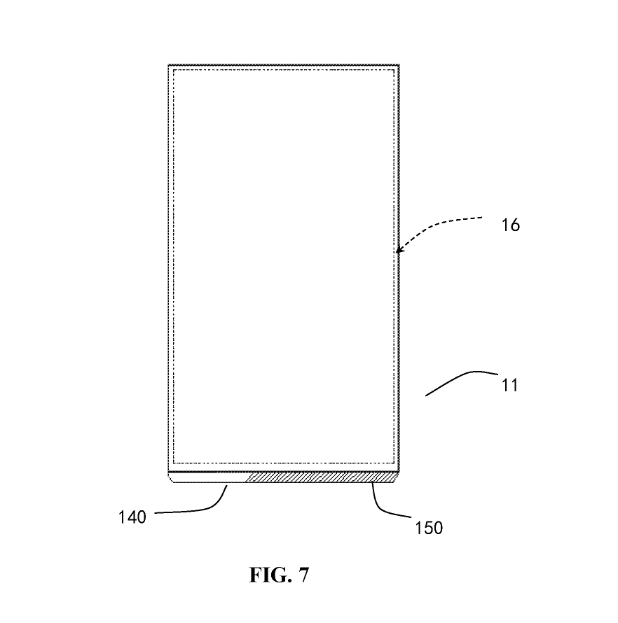

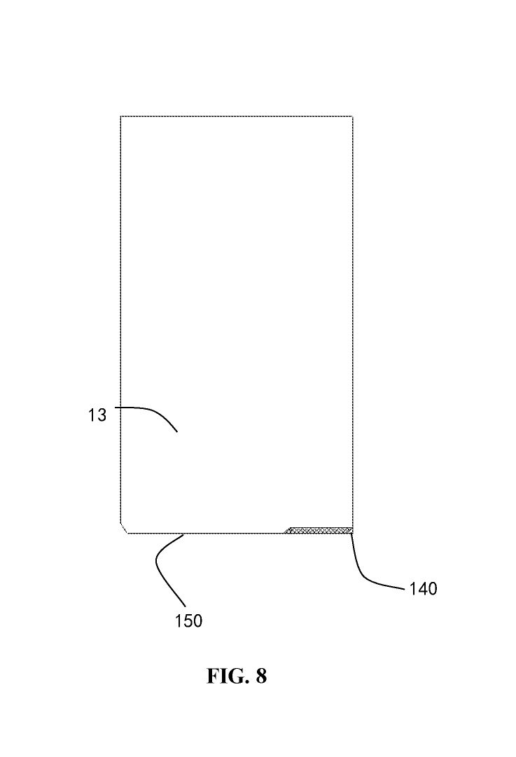

With reference to FIGS. 7 and 8, when the first connection area 150 is located on the right side of the bottom of the LTPS glass 13 located outside of the active area 160 of the OLED display 10, the right side of the bottom of the cover glass 12 aligned with the first connection area 150 is cut away to expose the first connection area 150. In this case, the second connection area 140 is located on the left side of the bottom of the cover glass 12 located outside of the active area 16 of the OLED display 10. The left side of the bottom of the LTPS glass 13 aligned with the second connection area 140 is cut away to expose the second connection area 140.

The method for producing an in-cell touch OLED display according to the present embodiment includes providing a low temperature poly-silicon (LTPS) glass 13. An organic electroluminescent device 15 is disposed on an upper face of the LTPS glass 13. Then, a cover glass 12 is provided. A touch sensing layer 14 is disposed on a lower face of the cover glass 12. The lower face of the cover glass 12 is glued to the upper face of the LTPS glass 13 by a frit to package the cover glass 12 and the LTPS glass 13.

Next, a first connection area 150 is defined on at least one side of the LTPS glass 13. A second connection area 140 is defined on at least one side of the cover glass 12. The first connection area 150 and the second connection area 140 do not overlap with each other.

Then, a portion of the cover glass 12 is cut away to form a first opening 121 in the cover glass 12. In this way, the first connection area 150 of the LTPS glass 13 is exposed via the first opening 121. A portion of the LTPS glass 13 is cut away to form a second opening 131 in the LTPS glass 13. In this way, the second connection area 140 of the cover glass 12 is exposed via the second opening 131.

Finally, the first connection area 150 is connected to a chip film, and the second connection area 140 is connected to a flexible printed circuit. In this way, the first connection area 150 of the LTPS glass 13 after sealing by gluing can be connected to the chip film or can serve as a basis for subsequent electric connection without changing the outline of the OLED display 10. The second connection area 140 of the cover glass 12 after sealing by gluing can be connected to the flexible printed circuit can serve as a basis for subsequent electric connection without changing the outline of the OLED display 10. By accomplishing the connection of the in-cell touch sensing layer 14 and the flexible printed circuit between the LTPS glass 13 and the cover glass 12 after sealing by gluing, the OLED display 10 includes an in-cell touch control structure.

In the in-cell touch OLED display 10 according to the present embodiment, the chip film and the flexible printed circuit are respectively connected to locations outside of the active area 16 of the OLED display 10, and the second opening 131 of the LTPS glass 13 and the first opening 121 of the cover glass 12 are located outside of the active area 16 of the OLED display 10, avoiding adverse influence on the effective emission of the OLED display 10. Furthermore, the present embodiment does not change the outline of the OLED display 10 and does not increase the length of the substrate glass or the cover glass 12, such that the rate of typesetting of the OLED display 10 is no changed. In this way, the frame of the OLED display 10 can be made narrower.

Although the disclosure has been described in connection with the embodiments shown in the accompanying drawings, a person having ordinary skill in the art can make various modifications to the disclosure based on the above descriptions. Therefore, some details of the embodiment should not be construed to restrict the disclosure. The scope of the disclosure is limited by the accompanying claims.

1. A method for producing an in-cell touch OLED display, comprising:
providing a low temperature poly-silicon (LTPS) glass, with an organic electroluminescent device disposed on an upper face of the LTPS glass;
providing a cover glass, with a touch sensing layer disposed on a lower face of the cover glass;
bonding the lower face of the cover glass to the upper face of the LTPS glass;
defining a first connection area on at least one side of the LTPS glass;
defining a second connection area on at least one side of the cover glass;
cutting a portion of the cover glass to leave the first connection area exposed for connection to a chip film; and
cutting a portion of the LTPS glass to leave the second connection area exposed for connection to a flexible printed circuit.

2. The method for producing an in-cell touch OLED display as claimed in claim 1, wherein the first connection area and the second connection area do not overlap with each other.

3. The method for producing an in-cell touch OLED display as claimed in claim 2, wherein the lower face of the cover glass is sealed to the upper face of the LTPS glass by a frit.

4. The method for producing an in-cell touch OLED display as claimed in claim 2, further comprising: disposing a polarizer on an upper face of the cover glass.

5. The method for producing an in-cell touch OLED display as claimed in claim 1, wherein a cutting angle in cutting the portion of the cover glass is between 0° and 180°, and wherein a cutting angle in cutting the portion of the LTPS glass is between 0° and 180°.

6. An in-cell touch OLED display comprising:
a low temperature poly-silicon (LTPS) glass, with an organic electroluminescent device disposed on an upper face of the LTPS glass;
a cover glass, with a touch sensing layer disposed on a lower face of the cover glass, with the lower face of the cover glass bonded to the upper face of the LTPS glass;
at least one side of the LTPS glass comprising a first connection area on, with the first connection area adapted to be connected to a chip film;
at least one side of the cover glass comprising a second connection area on, with the second connection area adapted to be connected to a flexible printed circuit;
a first opening in the cover glass and the first connection area of the LTPS glass exposed via the first opening; and
a second opening in the LTPS glass and the second connection area of the cover glass exposed via the second opening.

7. The in-cell touch OLED display as claimed in claim 6, wherein the first connection area and the second connection area do not overlap with each other.

8. The in-cell touch OLED display as claimed in claim 7, wherein the first connection area is located on a left side of a bottom of the LTPS glass located outside of an active area of the OLED display, and wherein the second connection area is located on a right side of a bottom of the cover glass located outside of the active area of the OLED display.

9. The in-cell touch OLED display as claimed in claim 7, the first connection area is located on a right side of a bottom of the LTPS glass located outside of an active area of the OLED display, and wherein the second connection area is located on a left side of a bottom of the cover glass located outside of the active area of the OLED display.

10. The in-cell touch OLED display as claimed in claim 7, wherein the lower face of the cover glass is sealed to the upper face of the LTPS glass by a frit.

11. The in-cell touch OLED display as claimed in claim 7, further comprising: a polarizer on an upper face of the cover glass.

12. The in-cell touch OLED display as claimed in claim 7, wherein a cutting angle in cutting the portion of the cover glass is between 0° and 180°, and wherein a cutting angle in cutting the portion of the LTPS glass is between 0° and 180°.
